(19) United States
(12) Patent Application Publication
(10) Pub. No.: US 2023/0335696 A1
(43) Pub. Date: Oct. 19, 2023

(54) SEMICONDUCTOR LIGHT EMITTING DEVICE AND SEMICONDUCTOR LIGHT EMITTING MODULE

(71) Applicant: STANLEY ELECTRIC CO., LTD., Meguro-ku, Tokyo (JP)

(72) Inventors: Keima KONO, Tokyo (JP); Koji ICHIKAWA, Tokyo (JP); Daizo KAMBARA, Tokyo (JP); Naochika HORIO, Tokyo (JP)

(73) Assignee: STANLEY ELECTRIC CO., LTD., Meguro-ku, Tokyo (JP)

(21) Appl. No.: 18/026,596

(22) PCT Filed: Sep. 21, 2021
(86) PCT No.: PCT/JP2021/034523

§ 371 Date: Mar. 16, 2023

(30) Foreign Application Priority Data
Sep. 24, 2020 (JP) 2020-159480

(51) Int. Cl. H01L 33/60; H01L 23/00; H01L 25/075; H01L 33/56

(52) U.S. Cl. CPC H01L 33/60; H01L 24/29; H01L 24/32; H01L 25/0753; H01L 33/56; H01L 2933/0058; H01L 2224/2919; H01L 2224/32225; H01L 2224/29188; H01L 2224/29286; H01L 2224/2939; H01L 2224/29388; H01L 33/62

(57) ABSTRACT

A semiconductor light emitting device includes: a light emitting element assembly including a semiconductor light emitting element including a support substrate and a light emitting semiconductor layer provided on the support substrate, and a light guide member adhered to the semiconductor light emitting element by an adhesive layer; and a first coating film formed of an inorganic material, which is a light reflector configured to cover a side surface of the light emitting element assembly.

### TECHNICAL FIELD

The present invention relates to a semiconductor light emitting device and a semiconductor light emitting module, and more specifically, to a semiconductor light emitting device having semiconductor light emitting elements such as light emitting diodes (LEDs) and semiconductor light emitting modules.

### BACKGROUND ART

In recent years, semiconductor light emitting elements such as light emitting diodes (LEDs) are arranged and used in a plurality of devices in order to increase an output or control light distribution.

For example, among vehicle headlights, an adaptive driving beam (ADB) that controls light distribution according to a traveling environment is known. In addition, an LED package for high-output illumination, an LED package for an information communication device in which LEDs are arranged at high density, or the like is known.

However, in a semiconductor light emitting device in which a plurality of semiconductor light emitting elements are arranged in parallel, a part of light emitted from a conductive element may generally propagate through a non-conductive element. Such leakage light or crosstalk of light arises as a problem in various application fields in which the plurality of semiconductor light emitting elements are arranged and used.

For example, Patent Literature 1 discloses that optical reflection layers are provided on side surfaces of a substrate and a light emitting element. In addition, Patent Literature 2 discloses a light emitting element that includes a reflection member covering side surfaces of a semiconductor stacked body and suppressing leakage of light to sides from an upper end of the side surface of the semiconductor stacked body.

Patent Literature 3 discloses a semiconductor light emitting device including a light reflection groove that suppresses crosstalk between light emitting segments.

### CITATION LIST

### Patent Literatures

Patent Literature 1: Japanese Patent Application Laid-Open No. 2015-225862

Patent Literature 2: Japanese Patent Application Laid-Open No. 2015-119063

Patent Literature 3: Japanese Patent Application Laid-Open No. 2015-156431

### SUMMARY OF INVENTION

### Technical Problem

The present invention has been made in view of the above-described points, and an object of the present invention is to provide a semiconductor light emitting device with high reliability and excellent airtightness, in which incidence of light leaking to the outside and external light is extremely suppressed. In addition, another object of the present invention is to provide a semiconductor light emitting module having high contrast and excellent light shielding property, airtightness, fixing property, and reliability, in which crosstalk of light between adjacent light emitting devices is extremely suppressed.

### Solution to Problem

A semiconductor light emitting device according to a first embodiment of the present invention includes:
a light emitting element assembly including a semiconductor light emitting element including a support substrate and a light emitting semiconductor layer provided on the support substrate, and a light guide member adhered to the semiconductor light emitting element by an adhesive layer; and
a first coating film formed of an inorganic material, which is a light reflector configured to cover a side surface of the light emitting element assembly.

### BRIEF DESCRIPTION OF DRAWINGS

FIG. 1A is a plan view schematically illustrating an upper surface of a semiconductor light emitting device 10 according to a first embodiment of the present invention.

FIG. 1B is a sectional view schematically illustrating a cross section of the semiconductor light emitting device 10 taken along line A-A of FIG. 1A.

FIG. 1C is a plan view schematically illustrating a back surface of the semiconductor light emitting device 10.

FIG. 2 is a sectional view schematically and detailedly illustrating an example of a configuration of an LED element 11, which is a semiconductor light emitting element.

FIG. 3A is a view describing a manufacturing method of the semiconductor light emitting device 10.

FIG. 3B is a view describing a manufacturing method of the semiconductor light emitting device 10.

FIG. 4A is a top view illustrating a semiconductor light emitting module 37 in which semiconductor light emitting devices are arranged in a 5×3 arrangement.

FIG. 4B is a sectional view illustrating a cross section taken along line A-A in FIG. 4A and schematically illustrating an application example of the semiconductor light emitting device 10 according to the present embodiment.

FIG. 4C is sectional views schematically illustrating cross sections of a semiconductor light emitting module 38 of Comparative Examples 1 and 2.

FIG. 4D is a view schematically illustrating a difference in a light emitting display pattern between the semiconductor light emitting module 37 used in the semiconductor light emitting device 10 of the present embodiment and the semiconductor light emitting module 38 used in semiconductor light emitting devices 90 of Comparative Examples 1 and 2.

FIG. 5A is a top view schematically illustrating another embodiment of the semiconductor light emitting module 37 in which the semiconductor light emitting devices 10 of the present embodiment are arranged in an irregular arrangement.

FIG. 5B is a sectional view schematically illustrating a cross section taken along the line A-A of FIG. 5A.

FIG. 6 is a sectional view schematically illustrating a cross section of a semiconductor light emitting module 50M in which a plurality of semiconductor light emitting devices 50 according to a second embodiment are arranged adjacent to each other.

FIG. 7 is a sectional view schematically illustrating a cross section of a semiconductor light emitting module 60M in which a plurality of semiconductor light emitting devices 60 according to a third embodiment are arranged adjacent to each other.

FIG. 8 is a sectional view schematically illustrating a cross section of a semiconductor light emitting module 70M in which a plurality of semiconductor light emitting devices 70 according to a fourth embodiment are arranged adjacent to each other.

FIG. 9 is a sectional view schematically and detailedly illustrating a configuration of an LED element 81 according to a fifth embodiment.

FIG. 10 is a sectional view schematically illustrating a configuration of a semiconductor light emitting device 90 according to a sixth embodiment.

### DESCRIPTION OF EMBODIMENTS

While the present invention is described below in terms of the presently preferred embodiments, appropriate modifications or combinations thereof are possible. In addition, in the following description and the appended drawings, parts which are substantially identical or equivalent have been assigned identical reference symbols in the description.

### First Embodiment

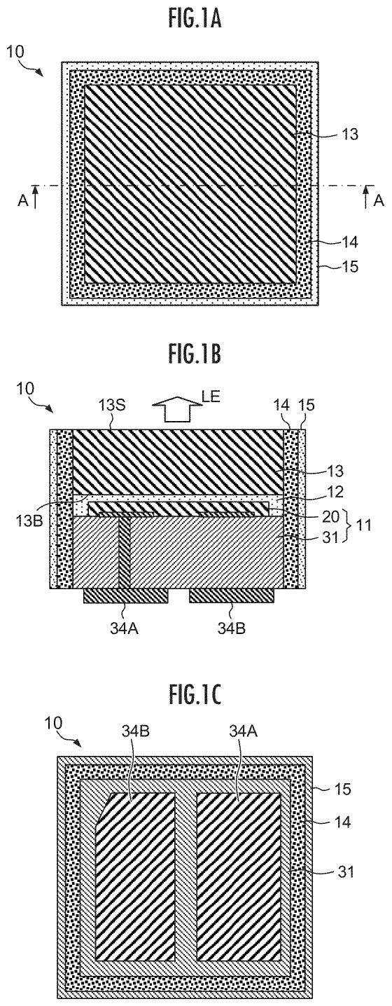

FIG. 1A is a plan view schematically illustrating an upper surface of a semiconductor light emitting device 10 according to a first embodiment of the present invention. FIG. 1B is a sectional view schematically illustrating a cross section of the semiconductor light emitting device 10 taken along line A-A of FIG. 1A. FIG. 1C is a plan view schematically illustrating a back surface of the semiconductor light emitting device 10.

The semiconductor light emitting device 10 includes a semiconductor light emitting element 11 and a light guide member 13 adhered onto the semiconductor light emitting element 11 by an adhesive layer 12 formed of an adhesive. In addition, the semiconductor light emitting device 10 includes an inner coating film 14 and an outer coating film 15, which cover side surfaces of the semiconductor light emitting element 11 and light guide member 13.

The semiconductor light emitting element 11 includes a light emitting semiconductor layer 20 provided on a support substrate 31. Although a light emitting diode (LED) will be described below as the semiconductor light emitting element 11 by way of example, a surface light emitting element such as a surface light emitting laser diode (LD) may be provided.

In the present embodiment, the support substrate 31 and light guide member 13 of the semiconductor light emitting element (hereinafter referred to as an LED element) 11, which is a light emitting diode (LED), have a rectangular shape. The side surfaces of the LED element 11, the adhesive layer 12, and the light guide member 13 are commonly covered by the inner coating film 14 (first coating film) and the outer coating film 15 (second coating film) formed in close contact with the outside of the inner coating film 14. The LED element 11, the adhesive layer 12, and the light guide member 13 are sealed by the inner coating film 14 and the outer coating film 15.

More specifically, the inner coating film 14 has light reflectivity, insulation property and airtightness, and the outer coating film 15 has light shielding property due to the light reflectivity or light absorbing property. That is, a stacked structure of the inner coating film 14 and the outer coating film 15 achieves both a high reflectivity for light from the inside of the coating film and a high light shielding property for light from the outside of the coating film.

A light-reflective white alumina-ceramic binder is used for the inner coating film 14. The ceramic binder is a dense white coating film in which particles forming the coating film is bonded to each other, and has a thickness of about several tens of μm and sufficient light reflectivity. Such an inner coating film 14 efficiently reflects light directed from the light guide member 13 toward the inner coating film 14.

A light-absorptive black alumina-ceramic binder is used for the outer coating film 15. In addition, since the outer coating film 15 shields a small amount of light leaking from the inner coating film 14, and simultaneously absorbs and shields stray light from the outside of the semiconductor light emitting device 10, contrast as a light source is improved. In addition, a coating film that reflects and shields light can be used as the outer coating film 15.

The inner coating film 14 and the outer coating film 15 preferably cover the entire side surface of a light emitting element assembly 11A in which the LED element 11, the adhesive layer 12, and the light guide member 13 are formed integrally. In addition, a gap between the semiconductor light emitting element 11 and the light guide member 13 is preferably filled with the adhesive layer 12.

As the inner coating film 14, a light-reflective ceramic binder such as white alumina, zirconia, magnesia, or titanium oxide or a light-reflective composite ceramic binder such as white alumina-zirconia can be used. In addition, a silicate-based binder formed of a metal silicate-based inorganic adhesive can be used, as an aggregate, with mixed particles of light-reflective ceramic particles having a reflectivity similar to the ceramic binder, such as white alumina, zirconia, and magnesia, or white light-reflective ceramic particles. The silicate-based binder is formed by producing a siloxane bond (Si—O—Si) due to heating around 100° C. after applying the inorganic adhesive. The silicate-based binder has heat resistance at around 1,000° C. and excellent weather resistance.

In addition, white alumina is alumina-based fine ceramic used for a manufacturing device of a semiconductor or liquid crystal, and has a color tone of white or ivory. In addition, a light-reflective composite ceramic binder such as white alumina-zirconia has higher reflectivity than a single ceramic binder because reflection characteristics at interfaces between alumina particles and zirconia particles having different reflectivities are improved. In addition, a component ratio is adjusted, such that it is possible to match a coefficient of linear expansion of the light emitting element assembly 11A and to suppress the occurrence of cracks or the like in the inner coating film 14.

As the outer coating film 15, the light-absorptive ceramic binder such as black alumina, zirconia, silicon nitride, and titanium carbide can be used. Alternatively, a corrosion-resistant metal coating film such as cermet, or a metal coating film having a passive film, which is a reflective metal such as an aluminum alloy or stainless steel (SUS) and has an oxide film of a metal contained in a surface thereof, can be used. In addition, a silicate-based binder can be used, as an aggregate, with a mixture of light-absorptive ceramic particles similar to the ceramic binder, such as black alumina, zirconia, silicon nitride and titanium carbide, or light-absorptive ceramic particles.

More specifically, examples of the black alumina include black alumina (AR(B)) (manufactured by ASUZAC Inc.) having a black color tone, so that it is possible to suppress a surface reflection while maintaining a strength and durability, which are features of fine ceramics (the reflectivity is 5.1% to 15.3% at a wavelength of 240 to 2,600 nm).

Further, examples of the black ceramic other than alumina include NPZ-96 (black zirconia), NPA-2 (black alumina+titanium carbide), NPN-3 (black silicon nitride), and the like which are manufactured by Nippon Tungsten Co., Ltd.

The outer coating film 15 may be omitted in applications that do not require light shielding and corrosion resistance provided by the outer coating film 15.

The light guide member 13 also functions as a sealing material on an upper surface side of the semiconductor light emitting device 10. Light emitted from the LED element 11 is incident on the light guide member 13 from a bottom surface 13B of the light guide member 13, emission light LE of the semiconductor light emitting device 10 is emitted from a surface of the light guide member 13 (light emission surface 13S).

As the light guide member 13, a ceramic phosphor plate containing a transparent glass plate, a sapphire plate, a resin plate, or a wavelength conversion member and formed of alumina+YAG:Ce and the like, a glass phosphor plate formed of glass+α or β sialon and the like, a resin phosphor plate formed of silicone resin+silicate:Ce and the like, and a monocrystalline or polycrystalline single crystal phosphor plate formed of YAG+Ce and the like, can be used.

As the adhesive layer 12, a resin, a low-melting-point glass, a nanometal oxide sintered body, or the like, which transmits light emitted by the LED element 11, can be used. In addition, a composite obtained by impregnating a porous nanometal oxide sintered body with the resin or low-melting-point glass can also be used. In addition, a diffusing agent and a light conversion member can be additionally provided in the adhesive layer 12.

An anode electrode 34A and a cathode electrode 34B are provided on the back surface of the semiconductor light emitting device 10, and function as external electrodes of the semiconductor light emitting device 10.

(1) Configuration of LED Element 11

FIG. 2 is a sectional view schematically and detailedly illustrating an example of a configuration of an LED element 11, which is a semiconductor light emitting element. The LED element 11 has a configuration in which an LED semiconductor layer 20, which is a so-called thin-film LED, is attached to the support substrate 31 as the light emitting semiconductor layer 20.

More specifically, the LED semiconductor layer (light emitting semiconductor layer) 20 has a configuration in which a semiconductor layer (thin-film LED) having an LED structure epitaxially grown on a growth substrate is removed from the growth substrate and attached to the support substrate 31. In the present embodiment, a p-type semiconductor layer, which is a growth superficial layer, is attached to the support substrate 31 as a lower surface, and an n-type semiconductor layer refers to a surface layer.

The support substrate 31 is an n-type substrate formed of silicon (Si) doped with phosphorous (P), arsenide (As), or the like.

The LED semiconductor layer 20 includes an n-type semiconductor layer 21, a light emitting layer 22, and a p-type semiconductor layer 23. Each of the n-type semiconductor layer 21 and the p-type semiconductor layer 23 include at least one semiconductor layer, and may include various semiconductor layers such as a barrier layer, a current diffusion layer, and a contact layer.

The LED semiconductor layer 20 is, for example, a blue light emitting LED semiconductor layer formed of a GaN-based semiconductor layer, but is not limited thereto. The light emitting layer 22 has, for example, a single quantum well (SQW) or multiple quantum well (MQW) structure.

The LED semiconductor layer 20 has a p-electrode 25A and an n-electrode 25B. The p-electrode 25A is bonded to a p-side substrate electrode 32A by a conductive p-side bonding layer 26, and the n-electrode 25B is bonded to an n-side substrate electrode 32B by a conductive n-side bonding layer 27.

The p-electrode 25A is formed of an ITO/Ni/Pt/Ag layer in which indium tin oxide (ITO), nickel (Ni), platinum (Pt), and silver (Ag) reflective films are sequentially formed on the p-type semiconductor layer 23. The n-electrode 25B is formed of a (Ti or Ni)/Pt/Au layer in which titanium (Ti) or nickel (Ni), platinum (Pt), and gold (Au) are sequentially formed on the n-type semiconductor layer 21.

The materials and structures of the p-electrode 25A and the n-electrode 25B are not limited to the above. The materials and structures thereof can be appropriately selected in consideration of characteristics such as extraction efficiency improvement by light reflection, ohmic characteristics, and element reliability (lifespan).

An element protective film 28A formed of SiO2 is provided on a side surface of the LED semiconductor layer 20. In addition, a substrate protective film 28B formed of SiO2 is provided on a surface of the substrate 31 (a side bonded to the LED semiconductor layer 20).

The p-side substrate electrode 32A is connected to a conductive via 33 and is electrically connected to the anode electrode 34A on the back surface of the semiconductor light emitting device 10 through the conductive via 33. The p-side substrate electrode 32A, the conductive via 33, and the anode electrode 34A are insulated from the support substrate 31 by a substrate insulating film 35 made of SiO2.

The n-side substrate electrode 32B is electrically connected to the cathode electrode 34B on the back surface of the semiconductor light emitting device 10 through the support substrate 31 which is a Si substrate.

(2) Manufacturing Method of Semiconductor Light Emitting Device 10

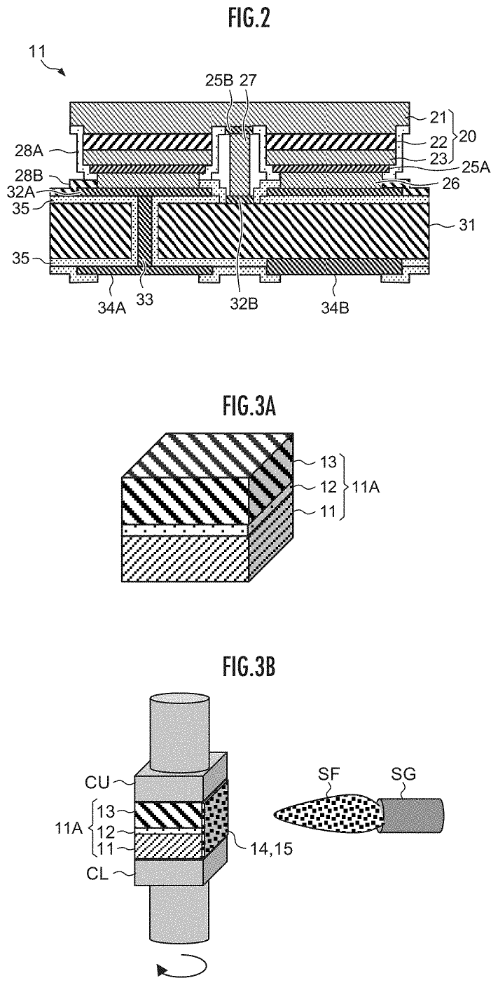

A manufacturing method of the semiconductor light emitting device 10 will be described below with reference to FIGS. 3A and 3B. First, as illustrated in FIG. 3A, the LED element 11 and the light guide member 13 are prepared.

An adhesive formed of a transparent silicone resin is potted on an upper surface (light emission surface) of the LED element 11. Subsequently, the light guide member 13 is placed on the LED element 11 and pressed (including self-weight pressing). The adhesive is allowed to stand until it is filled between an outer periphery of an upper end of the LED element 11 and an outer periphery of a lower end of the light guide member 13.

The adhesive is cured by performing a heat treatment at 180° C. for 30 minutes in an oven to form the adhesive layer 12. As a result, a light emitting element assembly (hereinafter referred to as an LED assembly) 11A in which the LED element 11, the adhesive layer 12 and the light guide member 13 are formed integrally is formed.

Next, as illustrated in FIG. 3B, the LED assembly 11A is set between an upper chuck CU and a lower chuck CL having substantially the same shape and size as a top surface of the light guide member 13 and a bottom surface of the LED element 11, respectively. Thereby, the top surface and bottom surface of the LED assembly 11A can be masked at the same time as the LED assembly 11A is fixed.

Subsequently, a thermal spray flame SF of a thermal spray gun SG passes through the LED assembly 11A by using white alumina as a welding material, while rotating (for example, 15 rpm) and preheating (180° C.) the chucks CU and CL. As a result, alumina-ceramic is thermally sprayed onto four side surfaces of the LED assembly 11A. An inner coating film 14 formed of white alumina with a thickness of about 50 μm was formed.

The inner coating film 14 formed by thermal spraying as described above is a ceramic binder in which ceramic particles are closely bonded to each other, and has excellent insulation property, airtightness, and weather resistance according to characteristics of the ceramic material. In other words, the inner coating film 14 is a ceramic sintered body in which a ceramic sintered body, which is a thermal spray material, is reconstructed into a film shape by thermal spraying.

The LED element 11 or the light guide member 13 is cut by dicing or the like and the side surface thereof has fine irregularities, such that alumina of the welding material can be firmly fixed by welding. The adhesive layer 12 can be satisfactorily fixed because the welding material eats into a resin surface.

That is, the LED element 11 or the light guide member 13 is airtightly sealed by the inner coating film 14. The adhesive layer 12 is also airtightly sealed. As a result, it is possible to provide a semiconductor light emitting device having excellent airtightness by applying the inner coating film 14 to the entire side surface of the LED assembly 11A.

In other words, the LED semiconductor layer 20 is included in the support substrate 31, the light guide member 13, and the adhesive layer 12, and the inner coating film 14 includes a surface excluding the surface (light emission surface 13S) and bottom surface of the LED assembly 11A. Therefore, it is possible to provide a semiconductor light emitting device in which the LED semiconductor layer 20 is airtightly sealed.

Similarly, the thermal spray flame SF passes through the LED assembly 11A on which the inner coating film 14 is formed by using black alumina as a welding material. As a result, the outer coating film 15 of black alumina was formed on the surface of the inner coating film 14 of white alumina. As a result, it is possible to provide a semiconductor light emitting device having excellent contrast and an extremely small amount of stray light that is shielded and leaks from the inner coating film 14 covering the LED semiconductor layer 20, the light guide member 13, and the adhesive layer 12.

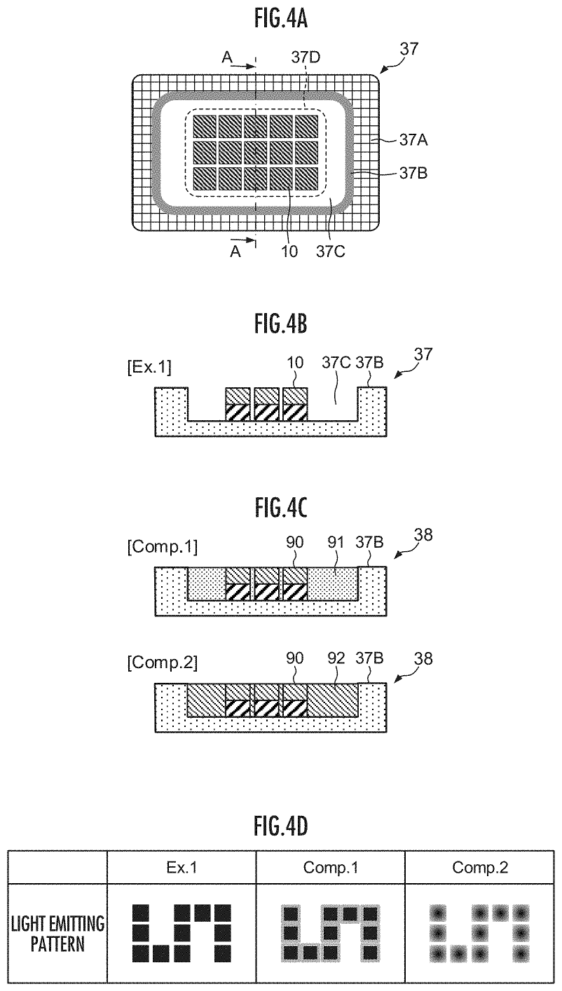

FIGS. 4A to 4D are views schematically illustrating a difference between the semiconductor light emitting device 10 of the present embodiment (Ex. 1) and a semiconductor light emitting device of Comparative Examples 1 and 2 (Comp. 1 and Comp. 2).

FIG. 4A is a top view illustrating a semiconductor light emitting module 37 in which semiconductor light emitting devices are arranged in a 5×3 arrangement. The semiconductor light emitting module 37 has a base 37A, a frame (frame body) 37B provided on the base 37A, and a recessed portion 37C in the frame 37B, and the semiconductor light emitting devices are arranged in the recessed portion 37C to be adjacent to each other at narrow intervals in a region 37D. The base 37A is provided with an electrode for supplying a current to each of the semiconductor light emitting devices, but the electrode is not illustrated. In addition, FIGS. 4B and 4C do not illustrate the base 37A outside the frame 37B.

FIG. 4B is a sectional view illustrating a cross section taken along line A-A in FIG. 4A and illustrates an application example of the semiconductor light emitting device 10 of the present embodiment (Ex. 1). The semiconductor light emitting devices 10 of the present embodiment are arranged in the recessed portion 37C of the semiconductor light emitting module 37 and are mounted on a wiring substrate (not illustrated), but a resin or the like for shielding light is not provided between the semiconductor light emitting devices 10. That is, a light shielding body such as a resin is not required between the semiconductor light emitting devices 10, and each of the semiconductor light emitting devices 10 is mounted separately by an air gap.

FIG. 4C illustrates a semiconductor light emitting module 38 of a Comparative Example, in which the semiconductor light emitting module 38 is the same as the semiconductor light emitting module 37 illustrated in FIG. 4A, but has semiconductor light emitting devices 90 of Comparative Examples 1 and 2 (Comp. 1 and Comp. 2) arranged in the frame.

The semiconductor light emitting device 90 of the Comparative Example is a semiconductor light emitting device in which the inner coating film 14 and the outer coating film 15 are not provided on side surfaces thereof, and side surfaces of the LED element 11 and light guide member 13 are exposed. The recessed portion 37C is filled with a resin as a light shielding material between each of the semiconductor light emitting devices. The recessed portion 37C is preferably filled with the light shielding resin so as to reach an upper surface of the semiconductor light emitting device 90.

More specifically, in Comparative Example 1 (Comp. 1), the recessed portion 37C is filled with a light-reflective resin 91 as a light shielding material. Specifically, the recessed portion 37C is filled with a white resin 91 in which TiO2 particles are contained in a silicone resin.

In Comparative Example 2 (Comp. 2), the recessed portion 37C is filled with a light-absorptive resin (grey resin) 92 as a light shielding material. Specifically, the recessed portion 37C is filled with the grey resin 92 in which TiO2 particles and carbon black are contained in the silicone resin.

FIG. 4D is a view schematically illustrating a difference in a light emitting display pattern between the semiconductor light emitting module 37 used in the semiconductor light emitting device 10 of the present embodiment (Ex. 1) and the semiconductor light emitting module 38 used in semiconductor light emitting devices 90 of Comparative Examples 1 and 2 (Comp. 1 and Comp. 2).

In addition, FIG. 4D schematically illustrates a state of brightness (light/dark) of the semiconductor light emitting device 90 when 11 of 15 semiconductor light emitting devices arranged in 5×3 arrangement are lit in an S shape. In order to easily illustrate the state of brightness (light/dark), the lighter the brightness, the darker the brightness.

As in Comparative Example 1 (Comp. 1), when a light shielding material 91 is a white resin, a display blurs due to light leaking from an outer peripheral portion of the light guide member (phosphor plate). In addition, crosstalk also occurs between the semiconductor light emitting devices 90.

As in Comparative Example 2 (Comp. 2), when a light shielding material 92 is a grey resin, the light shielding material 92 causes a large amount of light absorption and a large reduction in brightness of the outer peripheral portion of the light guide member (phosphor plate).

On the other hand, in the semiconductor light emitting device 10 of the present embodiment (Ex. 1), light-reflective ceramic is used as a coating film to cover the side surface of the semiconductor light emitting device, so that light cannot leak to the side of the device and a light emitting pattern (display pattern) with high contrast can be made.

In addition, even when the semiconductor light emitting devices are lit separately, the semiconductor light emitting devices can be mounted with high density because an adjacent distance between the semiconductor light emitting devices without crosstalk can be reduced.

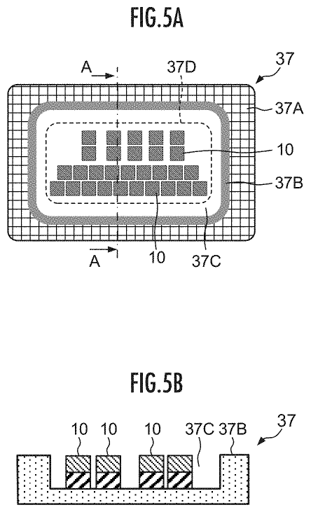

FIG. 5A is a top view schematically illustrating another embodiment of the semiconductor light emitting module 37 in which the semiconductor light emitting devices 10 of the first embodiment are arranged in an irregular arrangement. FIG. 5B is a sectional view illustrating a cross section taken along the line A-A of FIG. 5A.

More specifically, in the semiconductor light emitting module 37, a plurality of semiconductor light emitting devices 10 are arranged at different arrangement intervals. In addition, the plurality of semiconductor light emitting devices 10 are mounted on a wiring substrate (not illustrated) of the base 37A. A resin or the like for shielding light between the semiconductor light emitting devices 10, such as the resin in the recessed portion 37C, is not provided, and each of the semiconductor light emitting devices 10 is mounted separately by an air gap.

Even in the semiconductor light emitting module in which the semiconductor light emitting devices are irregularly arranged, such as the function arrangement type, a light emitting pattern without change in contrast can be obtained by widening or narrowing an arrangement interval. In addition, even if a covering member such as a resin is not filled between the semiconductor light emitting devices, the black outer coating film 15 absorbs light from the adjacent semiconductor light emitting devices, so that stray light is not generated.

According to the semiconductor light emitting device of the present embodiment, it is possible to provide a semiconductor light emitting device having high performance and high light emitting efficiency, in which light leakage to the outside of the light emitting device and incidence of external light are extremely suppressed. In addition, it is possible to provide a semiconductor light emitting device having excellent airtightness and high reliability.

Further, even if the plurality of semiconductor light emitting devices are arranged, crosstalk between the respective light emitting devices is significantly suppressed, such that it is possible to provide a semiconductor light emitting module without change in contrast by widening or narrowing the arrangement interval.

### Second Embodiment

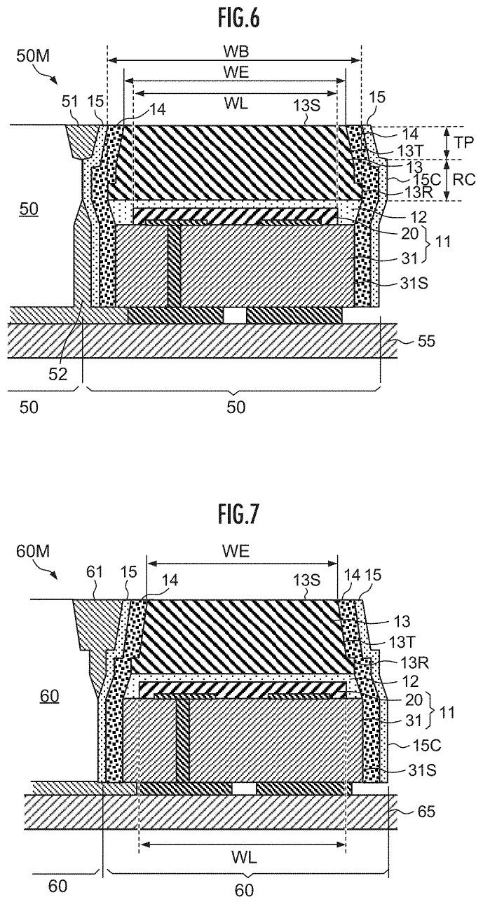

FIG. 6 is a sectional view schematically illustrating a cross section of a semiconductor light emitting module 50M in which a plurality of semiconductor light emitting devices 50 according to a second embodiment of the present invention are arranged adjacent to each other. FIG. 6 illustrates a cross section including a center line (line A-A illustrated in FIG. 1A) of the semiconductor light emitting device 50, in a plane perpendicular to the semiconductor light emitting device 50.

The semiconductor light emitting module 50M is formed by mounting the plurality of semiconductor light emitting devices 50 on a circuit board 55 having an electrode layer formed on a surface thereof so that side surfaces of the plurality of semiconductor light emitting devices 50 are in contact with each other.

In the semiconductor light emitting device 50, an outer edge of a bottom portion of the light guide member 13 (adhesive layer 12 side) has a prismatic shape, and the bottom portion is larger than an outer edge of the LED element 11. That is, a rim (peripheral portion) 13R protruding from the side surface is provided at the bottom portion of the light guide member 13.

Further, the light guide member 13 has a frustum portion 13T formed on the bottom portion (rim 13R). More specifically, the light guide member 13 has the frustum portion 13T of a truncated pyramid shape in which an area is reduced from the bottom portion (rim 13R) toward the surface (light emission surface 13S), that is, in a vertical direction of the LED semiconductor layer 20.

The rim 13R is not limited to a prismatic shape, and may have a cylindrical shape or a frustum shape such as a truncated pyramid shape or a truncated cone shape. In addition, the frustum portion 13T is not limited to a truncated pyramid shape, and may have a frustum shape such as a truncated cone shape.

The inner coating film 14 and the outer coating film 15 are formed on the side surface of the LED assembly 11A in which the LED element 11, the adhesive layer 12, and the light guide member 13 are formed integrally. Therefore, as illustrated in FIG. 6, the semiconductor light emitting device 50 has a protruding prismatic portion RC corresponding to the rim 13R and a truncated pyramid portion TP having a smaller outer edge than the prismatic portion RC and located closer to the surface side than the prismatic portion RC.

The prismatic portion RC has a side surface 15C (surface of the outer coating film 15) protruding from the side surface of the semiconductor light emitting device 50. The side surface 15C of the semiconductor light emitting device 50 and the side surfaces 15C of the adjacent semiconductor light emitting devices 50 are butted against each other so as to be in surface contact with each other, and the semiconductor light emitting devices 50 adjacent to each other are bonded to each other.

The rim 13R can be formed, for example, by a dicing blade used to cut the semiconductor light emitting device 50 into individual pieces from a semiconductor wafer. Since the rim 13R is provided, adhesion between the inner coating film 14 and the outer coating film 15 is improved. In addition, the rim 13R can prevent the adhesive layer 12 from climbing up and serve as a marker, such that alignment accuracy is improved.

The light guide member 13 has a size and arrangement such that the bottom surface of the light guide member 13 includes the LED semiconductor layer 20 when viewed in the vertical direction of the LED semiconductor layer 20 (hereinafter referred to as when viewed from above). More specifically, a width WB of the bottom surface of the light guide member 13 is larger than a width WL of the LED semiconductor layer 20. The light guide member 13 may be formed to have a size and arrangement such that the bottom surface of the light guide member 13 includes a light emitting layer (not illustrated) of the LED semiconductor layer 20 when viewed from above.

Further, the width WE of the light emission surface 13S of the light guide member 13 is larger than the width WL of the LED semiconductor layer 20. That is, the light emission surface 13S of the light guide member 13 has a size to include the LED semiconductor layer 20 when viewed from above. Therefore, the light emission surface is large and a luminous flux is large.

As illustrated in FIG. 6, in the light emission surface side of the semiconductor light emitting devices 50 adjacent to each other, a groove 51, which is a gap between the adjacent semiconductor light emitting devices 50, is formed. More specifically, the semiconductor light emitting device 50 is formed with the groove 51 which has the prismatic portion RC (surface of the outer coating film 15) protruding from the semiconductor light emitting device 50, has the side surface 15C colliding with the side surface 15C of the prismatic portion RC of the semiconductor light emitting device 50 adjacent to the semiconductor light emitting device 50, and is formed between the truncated pyramid portions TP of the adjacent semiconductor light emitting devices 50.

In the semiconductor light emitting module 50M, the groove 51 is filled with a resin that is a light reflector or a light absorber, that is, a resin such as a so-called white resin or black resin. For example, the groove 51 is filled with a light-reflective white resin, a light-absorptive black resin, or the like in which TiO2 particles are dispersed in the silicone resin.

In addition, for example, when a white resin is used, the TiO2 particles can be blackened (particularly the surface portion) by laser treatment of the resin (for example, a wavelength of 355 nm) to further enhance the light shielding property. In this case, when the semiconductor light emitting module 50M is viewed from above the surface, the groove 51 functions as a black stripe or a black grid provided between the adjacent semiconductor light emitting devices 50, and contrast of the semiconductor light emitting module 50M can thus be improved.

Furthermore, the support substrate 31 of the LED element 11 has a size to include the LED semiconductor layer 20 when viewed from above. In addition, the rim 13R of the light guide member 13 has a size to include the support substrate 31 when viewed from above.

Therefore, a gap is generated between the bottom portions of the adjacent semiconductor light emitting devices 50. The gap is filled with a light-reflective white resin, a light-absorptive black resin, or the like to form an underfill 52. The underfill 52 improves protection and fixing stability of the adjacent semiconductor light emitting devices 50.

According to the semiconductor light emitting module of the present embodiment, light leakage to the adjacent light emitting devices and crosstalk of light due to external light from the adjacent light emitting devices and the like are extremely suppressed, such that it is possible to provide a semiconductor light emitting module having high contrast, high performance, and high light emitting efficiency.

Further, it is possible to provide a semiconductor light emitting module having high adhesion between the inner coating film 14 and the outer coating film 15 and excellent light shielding property, airtightness, fixing stability, and reliability. In addition, it is possible to provide a semiconductor light emitting module without change in contrast by widening or narrowing the arrangement interval.

### Third Embodiment

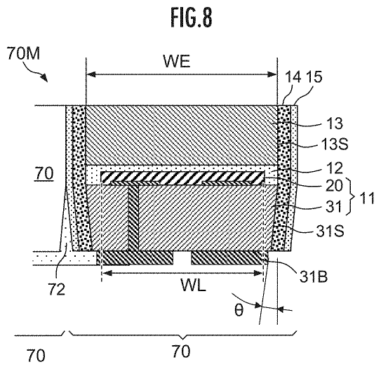

FIG. 7 is a sectional view schematically illustrating a cross section of a semiconductor light emitting module 60M in which a plurality of semiconductor light emitting devices 60 according to a third embodiment of the present invention are arranged adjacent to each other. FIG. 7 illustrates a cross section including a center line (line A-A illustrated in FIG. 1A) of the semiconductor light emitting device 60.

The semiconductor light emitting module 60M is formed by mounting the plurality of semiconductor light emitting devices 60 on a circuit board 65 in which an electrode layer is formed on a surface thereof.

The semiconductor light emitting device 60 is provided with a rim 13R as in the second embodiment. Further, the light guide member 13 has a frustum portion 13T formed on the bottom portion (rim 13R).

The semiconductor light emitting device 60 is different from the semiconductor light emitting device 50 of the second embodiment in that the width WE of the light emission surface 13S of the light guide member 13 is smaller than the width WL of the LED semiconductor layer 20.

That is, the LED semiconductor layer 20 has a size to include the light emission surface 13S of the light guide member 13 when viewed from above. Therefore, it is possible to provide a semiconductor light emitting module having high brightness.

Further, as in the second embodiment, a groove 61, which is a gap between the adjacent semiconductor light emitting devices 60, is formed in the light emission surface side of the semiconductor light emitting devices 60 adjacent to each other. More specifically, the groove 61 is formed between the adjacent semiconductor light emitting devices 60, in which the side surface 15C of the prismatic portion protruding from the semiconductor light emitting device 60, that is, a surface of the outer coating film 15 formed on the side surface of the support substrate 31 collides with the side surface 15C of the semiconductor light emitting device 60 adjacent to the semiconductor light emitting device 60.

The groove 61 is filled with a resin such as a light-reflective white resin or a light-absorptive black resin. Therefore, the light shielding property between the semiconductor light emitting devices 60 is high.

Further, the groove 61 is formed at a depth reaching the bottom surface of the LED semiconductor layer 20. Therefore, the light shielding property between the semiconductor light emitting devices 60 is extremely high.

According to the semiconductor light emitting module of the present embodiment, it is possible to provide a semiconductor light emitting module having high brightness and a light emission surface smaller than the light emission surface of the LED semiconductor layer 20, while having an advantage which is the same as that of the semiconductor light emitting module of the second embodiment. In addition, it is possible to provide a semiconductor light emitting module having extremely excellent light shielding property between the semiconductor light emitting devices 60.

### Fourth Embodiment

FIG. 8 is a sectional view schematically illustrating a cross section of a semiconductor light emitting module 70M in which a plurality of semiconductor light emitting devices 70 according to a fourth embodiment of the present invention are arranged adjacent to each other. The semiconductor light emitting module 70M has the plurality of semiconductor light emitting devices 70 mounted on a circuit board (not illustrated).

In the present embodiment, the support substrate 31 of the LED element 11 has an inverted trapezoidal shape in which an area of a bottom surface 31B is smaller than an area of a top surface thereof. The support substrate 31 has a tapered side surface 31S inclined at an angle θ.

Further, the light guide member 13 of each of the semiconductor light emitting devices 70 has a rectangular shape, and the semiconductor light emitting devices 70 are arranged so that side surfaces of the outer coating film 15 are in contact with each other. A gap corresponding to the tapered side surface 31S of the support substrate 31 is formed in the bottom portion between the adjacent semiconductor light emitting devices 70, and an underfill 72 is formed in the gap.

The underfill 72 improves protection and fixing stability of the adjacent semiconductor light emitting devices 50. Therefore, according to the present embodiment, it is possible to provide a semiconductor light emitting module having high fixing property, in addition to the above-described advantages.

### Fifth Embodiment

FIG. 9 is a sectional view schematically and detailedly illustrating a configuration of an LED element 81 according to a fifth embodiment of the present invention. A configuration of a p-side electrode portion is different from that of the LED element 11 illustrated in FIG. 2.

More specifically, the LED element 81 of the present embodiment is provided with a p-electrode 82, which is a transparent electrode formed of ITO, on the p-type semiconductor layer 23. p-auxiliary electrodes 83 formed in line and electrically connected to each other are provided on the p-electrode 82. The p-auxiliary electrode 83 is a metal electrode and is formed of, for example, a (Ti or Ni)/Pt/Au layer.

Further, an insulating film 84 that covers side surfaces of the p-electrode 82, the p-auxiliary electrodes 83, and the LED semiconductor layer 20 is provided. An n-electrode 85, which also functions as a reflective electrode, is provided on the insulating film 84 to face the p-electrode 82. As the n-electrode 75, Ag (silver) having high reflectivity or the like is used. The n-electrode 85 is electrically connected to the n-electrode 25B formed on the n-type semiconductor layer 21 in the LED element 11.

A part of the p-auxiliary electrode 83 is bonded to the p-side substrate electrode 87 by a conductive p-side bonding layer 86. The p-side substrate electrode 87 is connected to a conductive via 33 and is electrically connected to the anode electrode 34A on the back surface of the LED element 71 through the conductive via 33.

High reflectivity can be obtained by the p-electrode (transparent electrode) 82, the insulating film 84 between the electrodes, and the n-electrode 85 which is a reflective electrode such as Ag.

In addition, a large-area capacitor is formed by the p-electrode (transparent electrode) 82, the n-electrode 85, and the insulating film 84 provided between these electrodes, thereby obtaining a superior electrostatic breakdown withstand voltage and high reliability.

Furthermore, a reflective layer containing Ag (silver) is disposed under a negative electric field as the n-electrode 85, migration due to +ionization or electrolysis can be suppressed and short circuit can be prevented, so that reliability can be improved.

In the above description, a capacitor is formed inside the LED element 81 as a method for improving the electrostatic breakdown withstand voltage of the semiconductor light emitting device 10, but the method for improving an electrostatic breakdown withstand voltage of the semiconductor light emitting device 10 is not limited thereto.

For example, a Zener diode may be formed on the support substrate 31. For example, when the Zener diode is applied to the LED element 11 illustrated in FIG. 2, a Zener diode (ZD) having a polarity opposite to that of the LED semiconductor layer 20 can be incorporated in parallel for a circuit on a side of a lower Si layer partitioned by an interlayer insulating film, by using a silicon on insulator (SOI) substrate including the lower Si layer, the interlayer insulating film, and an upper Si layer as the support substrate 31.

In this case, specifically, the p-side substrate electrode 32A and the n-side substrate electrode 32B, to which the p-electrode 25A and n-electrode 25B of the LED element 11 are connected by the bonding layers 26 and 27, are connected to the anode electrode 34A and cathode electrode 34B on the back side of the semiconductor light emitting device 10 through conductive vias, respectively, and the Zener diode (ZD) is connected between the anode electrode 34A and the cathode electrode 34B through the lower Si layer.

Further, for example, it is possible to stack and mount a protective element, such as a Zener diode, a varistor, or a capacitor, including a pair of electrodes that can connect the anode electrode 34A and the cathode electrode 34B on a surface facing the support substrate 31 and a pair of electrodes that can be mounted on a circuit board (not illustrated) on the opposite surface, in a cubic (plate-like) shape having the same outer shape as the support substrate 31 of the light emitting element 11 when viewed from above. In this case, the protective element covers the inner coating film 14 and the outer coating film 15, such that it is possible to provide an integrated semiconductor light emitting device.

### Sixth Embodiment

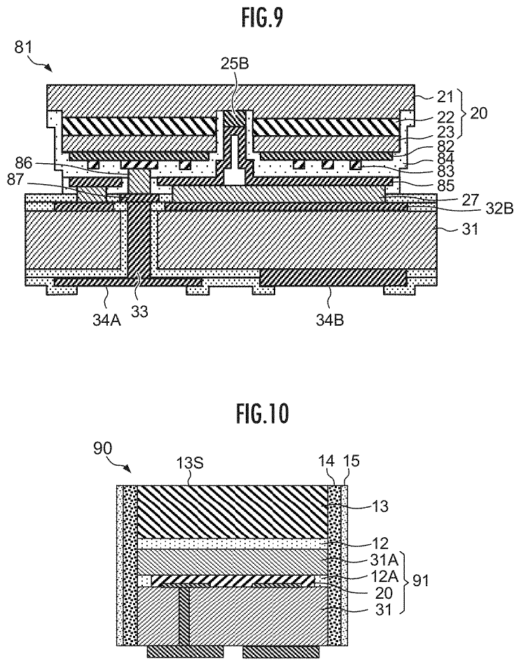

FIG. 10 is a sectional view schematically illustrating a configuration of a semiconductor light emitting device 90 according to a sixth embodiment of the present invention. The semiconductor light emitting device 90 is different from the semiconductor light emitting device 10 illustrated in FIG. 1B in that an LED element 91 is used instead of the LED element 11.

More specifically, the LED element 11 uses the LED semiconductor layer 20 which is a thin-film LED. However, the LED element 91 of the present embodiment has a configuration in which the LED semiconductor layer 20 epitaxially grown on the transparent growth substrate 31A is provided and a surface side of the LED semiconductor layer 20 is attached to the support substrate 31. In the LED element 91, a LED chip including the growth substrate 31A and the LED semiconductor layer 20 is adhered to the support substrate 31 by the adhesive layer 12A.

Specifically, the semiconductor light emitting device 90 includes the LED element 91 and the light guide member 13 adhered onto the growth substrate 31A of the LED element 91 by an adhesive layer 12 formed of an adhesive. In addition, the semiconductor light emitting device 90 includes an inner coating film 14 and an outer coating film 15, which cover side surfaces of the semiconductor light emitting element 91 and light guide member 13.

In the present embodiment, the side surface of the growth substrate 31A of the semiconductor light emitting element 91 is also covered with the inner coating film 14 and the outer coating film 15 to shield light.

According to the present embodiment, as in the semiconductor light emitting device of the above embodiment, it is possible to provide a semiconductor light emitting device having excellent airtightness and high reliability, in which light leakage is extremely suppressed. In addition, it is possible to provide a simple semiconductor light emitting device having a low cost without the need to remove the growth substrate.

In the above embodiment, a case where a semiconductor light emitting element substrate, the light guide member, and the like have a rectangular shape or a prismatic shape has been described by way of example, but the present invention is not limited thereto. It is possible to appropriately modify and apply a polygonal column shape, a cylindrical shape, polygonal truncated pyramid shape, a truncated cone shape, and the like according to an arrangement form, such as a case where the semiconductor light emitting element substrate and the light guide member are arranged adjacent to each other on the circuit board.

As described in detail above, according to the present invention, it is possible to provide a semiconductor light emitting device having excellent airtightness and high reliability by extremely suppressing light leakage and incident of external light to the outside of the light emitting device.

Further, it is possible to provide a semiconductor light emitting module having high contrast and excellent light shielding property, airtightness, fixing stability, and reliability, in which light leakage from the adjacent light emitting devices and crosstalk of light from the adjacent light emitting devices are extremely suppressed. In addition, it is possible to provide a semiconductor light emitting module which can prevent secondary light emission due to incident external light and surely turn off the semiconductor light emitting device that is not driven so as to be suitable for high-density arrangement and local dimming lighting.

Further, it is possible to provide a semiconductor light emitting device which can have a superior electrostatic breakdown withstand voltage, suppress migration, and prevent short circuit, and a semiconductor light emitting module.

### DESCRIPTION OF REFERENCE NUMERALS

10, 50, 60, 70, 90: semiconductor light emitting device
11, 81, 91: semiconductor light emitting element
11A: light emitting element assembly
12: adhesive layer
13: light guide member
13S: light emission surface
13T: frustum portion
13R: rim
14: inner coating film
15: outer coating film
20: light emitting semiconductor layer
21: n-type semiconductor layer
22: light emitting layer
23: p-type semiconductor layer
25A: p-electrode
25B: n-electrode
26, 27: bonding layer
31: support substrate
31B: bottom surface of support substrate
31S: side surface of support substrate
33: conductive via
34A: anode electrode
34B: cathode electrode
50M, 60M, 70M:
51, 61: groove
52, 72: underfill
55, 65: circuit board
RC: prismatic portion
TP: pyramid portion
WB: width of bottom surface of light guide member 13
WE: width of light emission surface 13S
WL: width of light emitting semiconductor layer 20

1. A semiconductor light emitting device comprising:
a light emitting element assembly including a semiconductor light emitting element including a support substrate and a light emitting semiconductor layer provided on the support substrate, and a light guide member adhered to the semiconductor light emitting element by an adhesive layer; and
a first coating film formed of an inorganic material, which is a light reflector configured to cover a side surface of the light emitting element assembly,
wherein the first coating film is (i) a ceramic binder that includes a white ceramic and is formed by thermally spraying or (ii) a silicate-based binder which includes a white ceramic and is an inorganic adhesive having a siloxane bond with ceramic particles as an aggregate.

2. (canceled)

3. The semiconductor light emitting device according to claim 1, wherein the first coating film is the silicate-based binder, and the silicate-based binder is formed by heating the inorganic adhesive.

4. The semiconductor light emitting device according claim 1, wherein the white ceramic contains any one of alumina, zirconia, and magnesia.

5. The semiconductor light emitting device according to claim 1, further comprising a second coating film formed of a light shielding inorganic material and making contact with an outside of the first coating film.

6. The semiconductor light emitting device according to claim 5, wherein the second coating film is a binder having a black ceramic or a metal having a passive film.

7. The semiconductor light emitting device according to claim 1, wherein the semiconductor light emitting element is a thin-film light emitting semiconductor layer attached onto the support substrate.

8. The semiconductor light emitting device according to claim 1, wherein the light guide member is formed to have a size and arrangement such that a bottom surface of the light guide member includes a light emitting layer of the semiconductor light emitting element, when viewed from above.

9. The semiconductor light emitting device according to claim 1, wherein the light guide member is provided with a rim at a bottom portion of the light guide member to protrude from a side surface of the light guide member.

10. The semiconductor light emitting device according to claim 8, wherein a light emission surface of the light guide member is formed to have a size and arrangement to include the light emitting layer of the semiconductor light emitting element, when viewed from above.

11. The semiconductor light emitting device according to claim 8, wherein a light emission surface of the light guide member is formed to have a size and arrangement to be included by the light emitting layer of the semiconductor light emitting element, when viewed from above.

12. The semiconductor light emitting device according to claim 9, wherein the rim has a prismatic shape, and the light guide member has a frustum portion formed on the rim and having a frustrum shape so that a cross-sectional area decreases toward a surface of the light guide member.

13. The semiconductor light emitting device according to claim 9, wherein a side surface having a prismatic shape corresponding to the rim is provided.

14. The semiconductor light emitting device according to claim 1, wherein the support substrate has tapered side surfaces that are inclined so that an area decreases from a top surface to a bottom surface of the support substrate.

15. A semiconductor light emitting module comprising:
a plurality of the semiconductor light emitting devices according to claim 13,
wherein side surfaces having the prismatic shape of the semiconductor light emitting devices are arranged in contact with each other, and
wherein a groove portion between adjacent semiconductor light emitting devices is filled with a resin, which is a light reflector or a light absorber, the groove portion being closer to the light emission surfaces than the side surfaces of the adjacent semiconductor light emitting devices.

16. A semiconductor light emitting module in which a plurality of the semiconductor light emitting devices according to claim 14 are arranged adjacent to each other, wherein a gap between the tapered side surfaces of the adjacent semiconductor light emitting devices is filled with an underfill.

17. The semiconductor light emitting device according to claim 1, wherein:
the light emitting semiconductor layer has a support substrate side formed as a p-semiconductor layer and a light guide member side formed as an n-semiconductor layer, and
a p-electrode is provided on the p-semiconductor layer, and the p-electrode includes a transparent electrode, a reflective electrode formed of a reflective metal, and an insulating film provided between the transparent electrode and the reflective electrode.

18. The semiconductor light emitting module according to claim 15, wherein, in each of the semiconductor light emitting devices:
the light emitting semiconductor layer has a support substrate side formed as a p-semiconductor layer and a light guide member side formed as an n-semiconductor layer, and
a p-electrode is provided on the p-semiconductor layer, and the p-electrode includes a transparent electrode, a reflective electrode formed of a reflective metal, and an insulating film provided between the transparent electrode and the reflective electrode.
